(19) United States
(12) Patent Application Publication
(10) Pub. No.: US 2019/0110377 A1
(43) Pub. Date: Apr. 11, 2019

(54) ALTITUDE CORRECTION METHOD AND SYSTEM FOR REGULATING AND CONTROLLING SERVER FAN

(71) Applicant: ZHENGZHOU YUNHAI INFORMATION TECHNOLOGY CO., LTD., Zhengzhou, Henan (CN)

(72) Inventor: Guangyi YU, Zhengzhou, Henan (CN)

(73) Assignee: ZHENGZHOU YUNHAI INFORMATION TECHNOLOGY CO., LTD., Zhengzhou, Henan (CN)

(21) Appl. No.: 16/097,095

(22) PCT Filed: Sep. 14, 2017
(86) PCT No.: PCT/CN2017/101722

§ 371 Date: Oct. 26, 2018

(30) Foreign Application Priority Data
Feb. 28, 2017 (CN) 201710114181.4

(51) Int. Cl. H05K 7/20; G06F 1/20; F04D 27/00; H02P 7/06

(52) U.S. Cl. CPC H05K 7/20727; G06F 1/206; H02P 7/06; F04D 27/004; F04D 27/002

(57) ABSTRACT

An altitude correction method and system for regulating a fan of a server are provided. In the altitude correction method for regulating the fan of the server, a correction parameter calculation formula for a duty cycle of a fan is fitted based on air densities at different altitudes, and the correction parameter obtained according to the correction parameter calculation formula is inputted to a fan regulating program as a variable. The fan regulating program increases or reduces a duty cycle of the fan required for heat dissipation of the fan based on the altitude, and regulates a rotational speed of the fan based on the duty cycle of the fan. An altitude input interface is reserved in the fan regulating program, and an altitude is inputted through the input interface.

### FIELD

The present disclosure relates to the technical field of heat dissipation of a server, and in particular to an altitude correction method and system for regulating a fan of a server.

### BACKGROUND

Computers have been widely applied due to advantages of a large amount of stored information and a convenient and fast way for users to acquire information. In recent years, with the further development of society and economy, performance requirements of the users for the computers are gradually increased. As compared with general purpose computers, the servers have better performances in stability, security and so on, and thus are widely applied in large enterprises. At present, an application scope of server products has been greatly extended. The servers are started to be applied to high-altitude areas such as the Qinghai-Tibet area on a large scale. However, a low air density in the high-altitude areas affects heat dissipation of the server. Therefore, it is required to increase a rotational speed of a fan in the server to meet an air volume requirement for heat dissipation of the server. The existing general server fan regulating strategy is designed based on an air density of low-altitude areas. In a case that the server is applied to the high-altitude areas, the general speed regulating strategy may results in a problem of the heat dissipation in the system. Therefore, a temperature of a component may exceed a standard value, and a failure of the component due to a high temperature is increased. In the conventional technology, a fan regulating strategy suitable for the altitude is customized by acquiring the altitude at which the server of the user is applied. Although the heat dissipation requirement of the server can be met with the above method, BMC versions of the server is increased, which requires a large amount of human resource, increases production cost, and affects a product delivery cycle and reduces work efficiency.

### SUMMARY

For the above problems, a technical objective in the present disclosure is to provide an altitude correction method for regulating a fan of a server, with which, a rotational speed of the fan of the server can meet a heat dissipation requirement at high altitudes, as the server is applied at different altitudes.

A further technical objective in the present disclosure is to provide an altitude correction system for regulating a fan of a server which can implement the above method.

To achieve the above objectives, the present disclosure provides the following technical solutions.

An altitude correction method for regulating a fan of a server is provided, which includes: fitting a correction parameter calculation formula for a duty cycle of the fan based on air densities at different altitudes, with the correction parameter calculation formula being represented as α=105/(105−11*h), where α denotes a correction parameter, and h denotes an altitude; inputting a correction parameter obtained according to the correction parameter calculation formula to a fan regulating program as a variable; and increasing or reducing, by the fan regulating program, a duty cycle of the fan required for heat dissipation of the fan based on the altitude, and regulating, by the fan regulating program, a rotational speed of the fan based on the duty cycle of the fan. An altitude input interface is reserved in the fan regulating program, and an altitude is inputted through the input interface.

Any altitude below 10000, rather than a specific altitude, can be inputted through the input interface, thereby broadening an application scope. In a case that no altitude data is inputted, a default altitude is 0, and a corresponding to the default value is 1. In a case that the altitude increases, a is a value greater than 1 by calculation.

With the altitude correction method for regulating the fan of the server, it can be ensured that the fan of a system can be speeded up in high altitude areas with a fan regulating strategy, to meet a heat dissipation requirement of the server under a low-density air condition, and avoid work caused by the development of customized fan speed regulating strategies for different altitudes. In a case that the server is used by a user, it is only required to input an altitude of a computer room, and a speed of the fan can be regulated based on the current altitude, to meet the heat dissipation requirement of the fan.

Preferably, the altitude correction method for regulating the fan of the server includes the following steps: step (1), starting altitude correction; step (2), determining an altitude of a computer room of a user; step (3), inputting the altitude to a fan regulating program; step (4): calculating a correction parameter according to a correction parameter calculation formula for a duty cycle of the fan; step (5), inputting the calculated correction parameter to the fan regulating program; step (6), calculating, by the fan regulating program, a duty cycle of the fan based on the correction parameter; and step (7), sending the duty cycle of the fan to the fan of a system to regulate a rotational speed of the fan.

After the inputting the calculated correction parameter to the fan regulating program in step (5), step (5) is not performed until the altitude changes. In step (6), the fan regulating program regulates the duty cycle of the fan to be outputted based on the correction parameter. The fan is regulated based on the correction parameter, to ensure that the rotational speed of the fan meets the heat dissipation requirement at the high altitude areas.

Preferably, the duty cycle of the fan outputted in the step (6) is represented as PWMₒᵤₜ=α*PWM, where α denotes the correction parameter, PWM denotes a normal duty cycle of the fan, and PWMₒᵤₜ denotes the outputted duty cycle of the fan. In a case that the calculated α is greater than 1, the calculated α is multiplied by the normal duty cycle of the fan to obtain the outputted duty cycle PWMₒᵤₜ of the fan. The rotational speed of the fan is regulated based on the outputted duty cycle PWMₒᵤₜ of the fan, so that the server meets the heat dissipation requirements for different altitudes.

An altitude correction system for regulating a fan of a server is provided, which includes: a calculating module configured to calculate a correction parameter for a duty cycle of the fan based on a different altitude; an inputting module configured to input the calculated correction parameter to a fan regulating program as a variable; an outputting module configured to output a duty cycle of the fan calculated based on the correction parameter; and a rotational speed regulating module configured to regulate a rotational speed of the fan based on the outputted duty cycle of the fan.

Preferably, the correction parameter for the duty cycle of the fan is calculated according to a correction parameter calculation formula for a duty cycle of the fan. The correction parameter calculation formula for the duty cycle of the fan is represented as α=105/(105−11*h), where α denotes a correction parameter, and h denotes an altitude.

Preferably, the duty cycle of the fan outputted by the outputting module is represented as PWMₒᵤₜ=α*PWM, where α denotes the correction parameter, PWM denotes a normal duty cycle of the fan.

As compared with the conventional technology, the altitude correction method for regulating a fan of the server in the present disclosure has the following outstanding advantageous effects. With the method, it can be ensured that the fan of the system is speeded up in high altitude areas with the fan regulating strategy, to meet the heat dissipation requirement of the server under a low-density air condition. In a case that the server is used by a user, it is only required to input an altitude of the computer room, and the fan can be regulated based on the current altitude, to meet the heat dissipation requirement of the fan, thereby avoiding work caused by the development of customized fan speed regulating strategies for different altitudes, reducing development cost, improving work efficiency and realizing good popularization and application value.

### BRIEF DESCRIPTION OF THE DRAWINGS

FIG. 1 is a flowchart of an altitude correction method for regulating a fan of a server in the present disclosure.

### DETAILED DESCRIPTION

An altitude correction method and system for regulating a fan of a server in the present disclosure is further described in detail below in conjunction with the drawings and the embodiments.

### First Embodiment

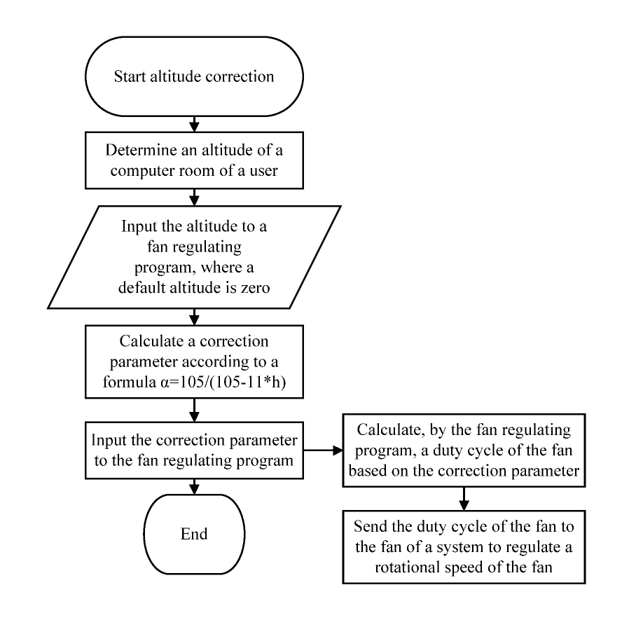

FIG. 1 shows an altitude correction method for regulating a fan of a server in the present disclosure. A correction parameter calculation formula for a duty cycle of a fan is fitted based on air densities at different altitudes. The correction parameter calculation formula is represented as α=105/(105−11*h), where α denotes a correction parameter, and h denotes an altitude. A correction parameter obtained according to the correction parameter calculation formula is inputted to a fan regulating program as a variable. The fan regulating program increases or reduces a duty cycle of the fan required for heat dissipation of the fan based on the altitude. The duty cycle of the fan is calculated according to a formula PWMₒᵤₜ=α*PWM, where α denotes the correction parameter, and PWM denotes a normal duty cycle of the fan. A rotational speed of the fan is regulated based on the duty cycle of the fan. An altitude input interface is reserved in the fan regulating program, and any altitude below 10000 can be inputted through the input interface.

The altitude correction method for regulating the fan of the server includes steps (1) to (7).

In step (1), altitude correction is started.

In step (2), an altitude of a computer room of a user is determined.

In step (3), the altitude is inputted to a fan regulating program.

In step (3), the actual altitude is inputted through an altitude input interface reserved in the fan regulating program. Any altitude below 10000 can be inputted through the input interface.

In step (4), a correction parameter is calculated according to a correction parameter calculation formula for a duty cycle of the fan which is represented as α=105/(105−11*h).

In step (5), the calculated correction parameter is inputted to the fan regulating program.

In step (6), the fan regulating program calculates the duty cycle of the fan based on the correction parameter. The duty cycle of the fan is calculated according to PWMₒᵤₜ=α*PWM, where α denotes a correction parameter, and PWM denotes a normal duty cycle of the fan.

In step (7), the duty cycle of the fan is sent to the fan of a system to regulate a rotational speed of the fan.

### Second Embodiment

An altitude correction system for regulating a fan of a server in the present disclosure includes a calculating module, an inputting module, an outputting module, and a rotational speed regulating module.

The calculating module is configured to calculate a correction parameter for a duty cycle of the fan based on an air density at a different altitude. A correction parameter calculation formula for the duty cycle of the fan is represented as α=105/(105−11*h), where α denotes a correction parameter, and h denotes an altitude.

The inputting module is configured to input the calculated correction parameter to a fan regulating program as a variable.

The outputting module is configured to output a duty cycle of the fan calculated based on the correction parameter. The duty cycle of the fan is calculated according to PWMₒᵤₜ=α*PWM, where α denotes the correction parameter, and PWM is a normal duty cycle of the fan.

The rotational speed regulating module is configured to regulate a rotational speed of the fan based on the outputted duty cycle of the fan, to meet a heat dissipation requirement of the server.

The above embodiments are only preferred embodiments of the present disclosure, general variations and substitutions made by those skilled in the art within the scope of technical solution of the present disclosure should fall within the protection scope of the present disclosure.

1. An altitude correction method for regulating a fan of a server, comprising:
fitting a correction parameter calculation formula for a duty cycle of a fan based on air densities at different altitudes, with the correction parameter calculation formula being represented as α=105/(105−11*h), wherein α denotes a correction parameter, and h denotes an altitude;
inputting a correction parameter obtained according to the correction parameter calculation formula to a fan regulating program as a variable; and
increasing or reducing, by the fan regulating program, a duty cycle of the fan required for heat dissipation of the fan based on the altitude, and regulating, by the fan regulating program, a rotational speed of the fan based on the duty cycle of the fan,
wherein an altitude input interface is reserved in the fan regulating program, and an altitude is inputted through the input interface.

2. The altitude correction method for regulating the fan of the server according to claim 1, comprising:
step (1): starting altitude correction;
step (2): determining an altitude of a computer room of a user;
step (3): inputting the altitude to the fan regulating program;
step (4): calculating a correction parameter according to the correction parameter calculation formula for the duty cycle of the fan;
step (5): inputting the calculated correction parameter to the fan regulating program;
step (6): calculating, by the fan regulating program, a duty cycle of the fan based on the correction parameter; and
step (7): sending the duty cycle of the fan to the fan of a system to regulate a rotational speed of the fan.

3. The altitude correction method for regulating the fan of the server according to claim 2, wherein the duty cycle of the fan outputted in the step (6) is represented as PWMₒᵤₜ=α*PWM, wherein α denotes the correction parameter, PWM denotes a normal duty cycle of the fan, and PWMₒᵤₜ denotes the outputted duty cycle of the fan.

4. An altitude correction system for regulating a fan of a server, comprising:
a calculating module configured to calculate a correction parameter for a duty cycle of a fan based on a different altitude;
an inputting module configured to input the calculated correction parameter to a fan regulating program as a variable;
an outputting module configured to output a duty cycle of the fan calculated based on the correction parameter; and
a rotational speed regulating module configured to regulate a rotational speed of the fan based on the outputted duty cycle of the fan.

5. The altitude correction system for regulating the fan of the server according to claim 4, wherein the correction parameter for the duty cycle of the fan is calculated according to a correction parameter calculation formula for a duty cycle of a fan, which is represented as α=105/(105−11*h), wherein α denotes a correction parameter, and h denotes an altitude.

6. The altitude correction system for regulating the fan of the server according to claim 5, wherein the duty cycle of the fan outputted by the outputting module is represented as PWMₒᵤₜ=α*PWM, wherein α denotes the correction parameter, and PWM denotes a normal duty cycle of the fan.
